(19) United States
(12) Patent Application Publication
(10) Pub. No.: US 2010/0215788 A1
(43) Pub. Date: Aug. 26, 2010

(54) MOLD AND METHOD FOR PRODUCING THE SAME

(75) Inventor: Takeo KIDO, Minamiashigara-shi (JP)

Correspondence Address: YOUNG & THOMPSON, 209 Madison Street, Suite 500, Alexandria, VA, 22314, US

(73) Assignee: FUJIFILM CORPORATION, Tokyo (JP)

(21) Appl. No.: 12/711,530

(22) Filed: Feb. 24, 2010

(30) Foreign Application Priority Data
Feb. 24, 2009 (JP) 2009-040134
Jan. 22, 2010 (JP) 2010-012218

(51) Int. Cl. B29C 59/02; C25D 5/16; C23C 14/46

(52) U.S. Cl. 425/3; 205/95; 427/128; 204/192.11

(57) ABSTRACT

A method for producing a mold having a fine groove-ridge pattern on the surface thereof is disclosed. The method includes: a release layer forming step of forming, on a surface of a Si original plate having a groove-ridge pattern, a release layer made of a metal film containing a metal having an ionization tendency lower than that of hydrogen (for example, at least one metal selected from the group consisting of Pt, Os, Ir, Au, Ru and Pd); an electroforming step of electroforming, after the release layer has been formed, a metal substrate forming a mold; and a releasing step of releasing a duplicated plate including the release layer and the metal substrate from the Si original plate after the electroforming step.

### BACKGROUND OF THE INVENTION

1. Field of the Invention

The present invention relates to a mold and a method for producing the mold. More particularly, the present invention relates to a method for producing a mold having a fine groove-ridge pattern on the surface thereof and a mold produced by the method, such as a magnetic transfer mold (master carrier) used during a step of magnetically transferring a magnetic information pattern (format information, etc.) to a medium to which information is transferred (also referred to as a slave medium), which is one of the steps of a process for producing a magnetic recording medium, such as a magnetic disk used in a hard disk device, a mold used to produce discrete track media (DTM), or a mold used for nanoimprint.

2. Description of the Related Art

A magnetic disk used in a hard disk drive is typically produced by writing, on a slave medium, format information and address information before it is disposed in the drive. The writing could be achieved using a magnetic head. However, it is more efficient and may be preferred to use a master carrier carrying the format information and the address information to transfer the information at a time.

In this magnetic transfer technique, a master carrier having a groove-ridge pattern of a magnetic layer and a slave medium are brought into close contact with each other, and a transfer magnetic field is applied thereto with magnetic field generating means, such as an electromagnet device or a permanent-magnet device, which is disposed on one side or opposite sides of the carrier and the medium, to transfer a magnetized pattern corresponding to the information (for example, servo signal) carried by the master carrier.

As one example of the master carrier used for the magnetic transfer, a master carrier has been proposed, which includes a groove-ridge pattern corresponding to an information signal formed on the surface of a substrate, and a thin-film magnetic layer coated on the surface of the groove-ridge pattern (see U.S. Patent Application Publication No. 20060177569, for example).

The groove-ridge pattern of the master carrier is formed as follows: writing the pattern with a laser or electron beam, which is modulated according to the information, on a Si original plate coated with a photoresist while rotating the Si original plate; developing the photoresist and forming the groove-ridge pattern on the Si original plate; forming a conductive layer for electroforming plating through sputtering, or the like, on the surface of the groove-ridge pattern of the Si original plate; carrying out electroforming plating on the conductive layer to provide a metal mold which will be a duplicated plate; and releasing the duplicated plate to produce the mold (master carrier) including the groove-ridge shape duplicated on the surface of the substrate.

The above-described mold (master carrier) for magnetic transfer requires a magnetic layer made of a material having high magnetic permeability. In the above technique disclosed in U.S. Patent Application Publication No. 20060177569, the magnetic layer is directly formed on the groove-ridge pattern of the Si original plate (the magnetic layer may also be used as the conductive layer, or a separate conductive layer may be formed on the magnetic layer), and then a metal plate serving as the substrate of the mold is formed through electroforming/plating. Therefore, a large joining force is present between the Si original plate and the magnetic layer, and it is difficult to release the duplicated plate.

Further, in order to directly form the substrate of the mold through electroforming on the groove-ridge pattern of the Si original plate, it is necessary to form the conductive layer in advance, such that, for example, a Ni conductive layer is formed through sputtering, and then the substrate of the mold is formed through electroforming/plating. In this case, although the Ni conductive layer is easier to be released than the above-described magnetic layer, there still remains a problem that duplicated ridge portions of the groove-ridge pattern on the mold may be chipped and precision of the pattern shape may be lowered when increasingly finer groove-ridge patterns are formed on Si original plates.

Moreover, in the case where the substrate of the mold is formed through electroforming, the electroforming solution is acidic. Therefore, when the Si original plate with the conductive layer formed thereon is immersed in the electroforming solution and a current is applied thereto, the conductive layer is dissolved by the acid of the electroforming solution and this causes poor electric conduction, which hinders formation of a desired substrate.

The above-described problems occur not only with master carriers for magnetic transfer, and are common among mold structures having a fine groove-ridge pattern on the surface.

In particular, when the aspect ratio of the ridge portions of the fine groove-ridge pattern of the Si original plate increases, that is, when a mold with a groove-ridge shape having narrower and higher (or higher ratio of the height to the width) ridge portions is produced, it is necessary to ensure good releasability of the mold (duplicated plate) from the Si original plate to suppress generation of chipped ridge portions.

The reason for the difficulty in releasing the duplicated mold (duplicated plate) from the Si original plate having the groove-ridge pattern with a high aspect ratio is, first, concentration of stress at the ridge portions of the high-aspect-ratio shape of the mold, which are formed in the groove portions of the groove-ridge pattern of the Si original plate. In particular, a large adhesion force to the Si original plate is present at opposite side surfaces of the tip of each ridge portions, and this causes the concentration of the stress when the mold is released from the Si original plate, which may result in chipped ridge portions.

In addition, in the case of production of the mold for magnetic transfer, if the magnetic layer is formed in the groove portions of the groove-ridge pattern of the Si original plate, as described above, a strong adhesion force is generated between the magnetic layer, such as a FeCo layer, or the like, and the Si original plate, and this also causes the concentration of the stress which may result in chipped ridge portions.

In order to improve releasability of the mold with respect to the Si original plate, it may be considered to coat an organic release agent on the Si original plate in advance. However, although the release agent provides improved releasability, the release agent may remain on the surfaces of the Si original plate and the mold and may cause an adhesion defect during a magnetic transfer step, etc.

### SUMMARY OF THE INVENTION

In view of the above-described circumstances, the present invention is directed to providing a mold and a method for producing the mold, which allow release of a duplicated plate formed on a groove-ridge shape of a Si original plate without generating chipped ridge portions of the duplicated plate, and allow repeated use of a single original plate.

An aspect of the method for producing a mold includes: a release layer forming step of forming, on a surface of a Si original plate having a groove-ridge pattern, a release layer made of a metal film containing a metal having an ionization tendency lower than that of hydrogen; an electroforming step of electroforming, after the release layer has been formed, a metal substrate to fill groove portions of the groove-ridge pattern; and a releasing step of releasing a duplicated plate including the release layer and the metal substrate from the Si original plate after the electroforming step, thereby providing the mold formed by the duplicated plate.

The “mold” herein is a structure having a desired groove-ridge pattern on the surface thereof. Examples of the mold may include a master carrier for magnetic transfer, which is used to transfer a magnetized pattern according to the shape of the groove-ridge pattern to a medium to which information is transferred, a mold for manufacturing discrete track media or bit pattern media, which is used to transfer the shape of the groove-ridge pattern to a medium to which information is transferred and a mold for nanoimprint, as well as a stamper for manufacturing optical disks, etc.

The “metal substrate” herein refers to a layer formed through the electroforming among layers forming the mold.

In the method for producing a mold, the metal film containing the metal having an ionization tendency lower than that of hydrogen in the release layer forming step may be a metal film containing at least one metal selected from the group consisting of Pt, Os, Ir, Au, Ru and Pd. In this case, the metal substrate may be formed through Ni electroforming.

This production method may further include, between the release layer forming step and the electroforming step, a magnetic layer forming step of forming a magnetic layer conforming to the groove-ridge pattern of the release layer.

The release layer may be formed through a process selected from sputtering, vapor deposition, ion plating, ALD (atomic layer deposition), CVD (chemical vapor deposition) and electroless plating.

The method may further include, between the release layer forming step and the electroforming step, a conductive layer forming step of forming a conductive layer, the conductive layer being made of a conductive metal and conforming to the groove-ridge pattern of the release layer.

Another aspect of the method for producing a mold of the invention includes: a release layer forming step of forming, on a surface of a Si original plate having a groove-ridge pattern, a release layer made of a metal film containing a metal having an ionization tendency lower than that of hydrogen; a filling layer forming step of forming, after the release layer has been formed, a filling layer to fill groove portions of the groove-ridge pattern; an electroforming step of electroforming a metal substrate after the filling layer has been formed; a releasing step of releasing from the Si original plate a duplicated plate including the release layer, the filling layer and the metal substrate after the electroforming step, thereby providing the mold formed by the duplicated plate. The filling layer may be made of a metal material.

In this production method, the metal film containing a metal having an ionization tendency lower than that of hydrogen in the release layer forming step may be a metal film containing at least one metal selected from the group consisting of Pt, Os, Ir, Au, Ru and Pd. In this case, the metal substrate may be formed through Ni electroforming.

The release layer may be formed through a process selected from sputtering, vapor deposition, ion plating, ALD, CVD and electroless plating.

This production method may further include, between the release layer forming step and the filling layer forming step, a magnetic layer forming step of forming a magnetic layer conforming to the groove-ridge pattern of the release layer.

The conductive layer forming step in the former aspect or the filling layer forming step in the latter aspect of the production method of the invention may form the conductive layer or the filling layer through a process selected from sputtering, vapor deposition, ion plating, ALD, CVD and electroless plating.

The above-mentioned sputtering may be bias sputtering or ion beam sputtering.

An aspect of the mold of the invention is a mold having a groove-ridge pattern, the mold includes: a metal substrate formed through electroforming and having a groove-ridge pattern; and a release layer disposed on a surface of the groove-ridge pattern of the metal substrate, the release layer being made of a metal film containing a metal having an ionization tendency lower than that of hydrogen.

The “surface of the groove-ridge pattern of the metal substrate” herein refers to the surface of the groove-ridge pattern as the shape of the metal substrate itself, or the surface of the groove-ridge pattern as the shape of a layer formed on the metal substrate which does not have the groove-ridge pattern, or the surface of any other layer formed on the groove-ridge pattern.

The metal film containing the metal having an ionization tendency lower than that of hydrogen of the mold may be a metal film containing at least one metal selected from the group consisting of Pt, Os, Ir, Au, Ru and Pd.

The mold may further include a magnetic layer conforming to the groove-ridge pattern, the magnetic layer being disposed between the metal substrate and the release layer. In this case, the metal substrate may be a Ni substrate formed through Ni electroforming.

The release layer may have a film thickness in the range from 1 to 30 nm, optionally in the range from 1 to 20 nm, or further optionally in the range from 2 to 10 nm.

The mold may further include, between the release layer and the metal substrate, a conductive layer made of a conductive metal and conforming to the groove-ridge pattern.

The metal forming the release layer is a metal having an ionization tendency lower than that of hydrogen, and examples thereof include a metal selected from Pt, Os, Ir, Au, Ru and Pd. The metal may optionally be Pt, Os or Ir, or may further optionally be Pt.

Since the release layer is as thin as 1 to 30 nm, the electric resistance thereof tends to largely increase when it is oxidized. The increased electric resistance may often cause poor electric conduction at an early stage of the electroforming, or such a failure that the electroformed film does not grow to completely fill the groove portions of the Si original plate. Therefore, it is necessary to form the release layer with a metal which has an ionization tendency lower than that of hydrogen and thus does not easily form an oxide.

According to the method for producing a mold of the invention, the presence of the release layer, which is made of the metal film containing a metal having an ionization tendency lower than that of hydrogen (for example, at least one metal selected from Pt, Os, Ir, Au, Ru and Pd), improves releasability of the duplicated plate with respect to the Si original plate. In other words, due to the presence of the release layer, which has an ionization tendency lower than that of hydrogen and thus is not easy to oxidize, a binding force between the Si original plate and the duplicated plate is reduced. This mitigates the concentration of stress at the ridge portions filling the groove portions of the groove-ridge pattern when the duplicated plate is released, thereby preventing generation of chipped ridge portions. Thus, a mold with good shape stability can be provided even when the groove-ridge pattern of the mold has a high aspect ratio.

Further, since the release layer is released as the duplicated plate from the Si original plate together with the metal substrate, the magnetic layer and/or the conductive layer formed after the release layer, repeated use of the Si original plate, which serves as an original mold of the groove-ridge pattern, can be achieved.

Furthermore, since the release layer is made of the metal having an ionization tendency lower than that of hydrogen, when the release layer is immersed in an acidic electroforming solution and a current is applied thereto during electroforming of the metal substrate, it does not dissolve in the electroforming solution. Thus, good releasability and conductivity are maintained, thereby allowing successful electroforming and releasing in the subsequent steps.

According to the mold of the invention, the surface of the groove-ridge pattern of the mold formed by the released duplicated plate is coated with the release layer, and therefore, adhesion defect, which occurs when an organic release agent is used, can be prevented.

Further, according to the invention, a fine groove-ridge pattern can be formed with high precision on a mold, thereby providing a mold with excellent transfer characteristics for magnetic transfer or shape transfer. In addition, use of the mold according to the invention allows transfer with stable quality.

That is, according to the invention, a mold with high reproducibility of a groove-ridge shape can be provided, which is free of deformation of ridge portions of the groove-ridge pattern even when the groove-ridge pattern has narrower and/or higher ridge portions. For example, as a mold for magnetic transfer, a master carrier which provides high quality signal through magnetic transfer can be provided. As a mold for shape transfer, a mold for nanoimprint, discrete track media or bit pattern media with high reproducibility of the transferred shape, or a stamper for high-quality optical disks, can be provided.

### BRIEF DESCRIPTION OF THE DRAWINGS

FIG. 1 is an enlarged perspective view of a part of a master carrier for magnetic transfer, which is a mold according to one embodiment of the invention,

FIG. 2 is a plan view illustrating the entire part of the master carrier for magnetic transfer shown in FIG. 1,

FIG. 3 shows sectional views illustrating steps of a process for producing the master carrier for magnetic transfer shown in FIG. 1,

FIG. 4 is an explanatory diagram about definition of a trapezoidal shape of a ridge portion of a duplicated plate,

FIG. 5 shows sectional views illustrating steps of a process for producing the master carrier according to another embodiment,

FIGS. 6A and 6B shows sectional views illustrating how a non-filled area is formed in the ridge portion of the duplicated plate,

FIG. 7 shows micrographs for comparison of patternability of duplicated plates of Example 1 of the invention provided with a Pt release layer and of Comparative Example 1 provided with a Ni release layer, and

FIG. 8 shows micrographs for comparison of patternability of duplicated plates of Example 2 of the invention provided with a Ru release layer and of Comparative Example 2 provided with a Ni release layer.

### DESCRIPTION OF THE PREFERRED EMBODIMENTS

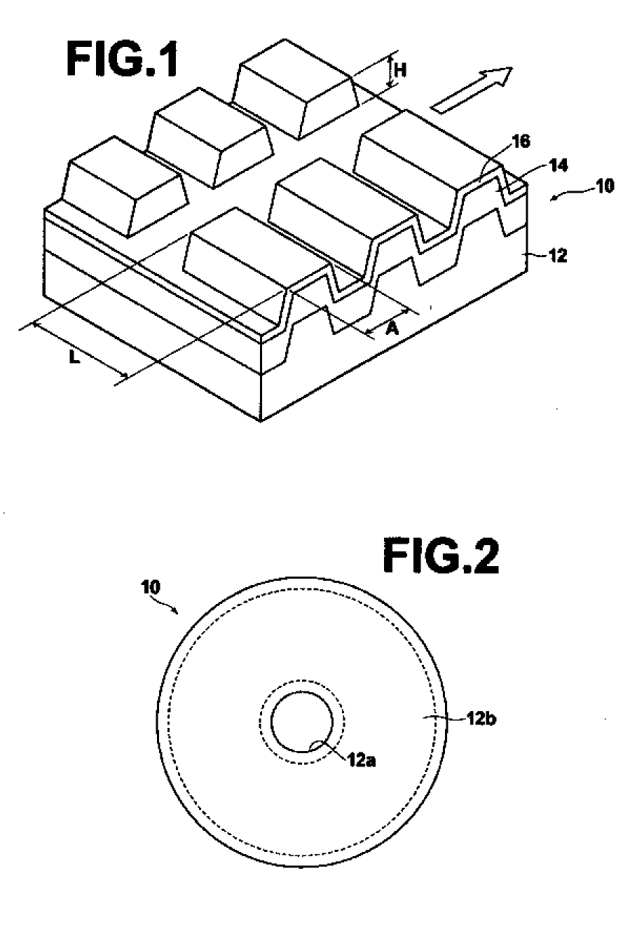

Hereinafter, embodiments of the present invention will be described in detail with reference to the drawings. FIGS. 1 and 2 show a mold according to embodiments of the invention, which is an example of a master carrier for magnetic transfer.

### Master Carrier

FIG. 1 is an enlarged perspective view of a part of the master carrier for magnetic transfer according to one embodiment, and FIG. 2 is a plan view illustrating the entire part of the master carrier for magnetic transfer shown in FIG. 1. For convenience of explanation, the drawings are not to scale.

As shown in FIG. 1, a master carrier 10 for magnetic transfer according to this embodiment includes a master substrate 12 made of metal, a magnetic layer 14 and a release layer 16. The master substrate 12 has on the surface thereof a fine groove-ridge pattern according to information to be transferred. The magnetic layer 14 is formed to coat the surface of the groove-ridge pattern. The release layer 16 is formed to coat the magnetic layer 14. Although not shown in the drawing, a protective layer and/or a lubrication layer may optionally be provided on the release layer 16.

Ridge portions of the fine groove-ridge pattern have a rectangular shape when viewed from above. Values of a length A in the track direction (direction of the arrow shown in FIG. 1), a length L in the track width direction (radial direction), and a height (thickness) H of the ridge portions are designed according to the recording density, the waveform of a recording signal, etc. For example, the length A may be 80 nm and the length L may be 200 nm.

In a case of a servo signal of a magnetic disk used in a hard disk device, the fine pattern is formed with a longer length L in the track width direction than the length A in the track direction. For example, if the length L in the track width direction is in the range from 0.05 to 20 μm, the length A in the track direction (circumferential direction) may be in the range from 0.05 to 5 μm. As a pattern carrying the servo signal information, a pattern with a longer length in the track width direction within this range may be selected.

The height H of the ridge portions (i.e., the depth of the groove portions) may be in the range from 20 to 800 nm, or may optionally be in the range from 30 to 600 nm.

As shown in FIG. 2, the entire shape of the master carrier 10 is a disk with a center hole 12a. The master carrier 10 has the groove-ridge pattern, as shown in FIG. 1, on one side thereof within an annular area 12b other than the inner circumferential area and the outer circumferential area of the disk.

It should be noted that, if the master substrate 12 of the master carrier 10 is made of a ferromagnetic material mainly composed of Ni, or the like, the magnetic transfer can be achieved only with the master substrate 12 without the magnetic layer 14 coated thereon. However, by providing the magnetic layer 14 with good transfer property, more successful magnetic transfer is achieved.

As will be described later, the master carrier 10 of this example is produced by: forming the release layer 16 and the magnetic layer 14 on a Si original plate (reversal-type original plate) with the groove-ridge pattern according to information to be transferred formed thereon; then, forming, on these layers, the master substrate 12 made of a Ni metal layer having a predetermined thickness through Ni electroforming; releasing a duplicated plate, which includes the release layer 16, the magnetic layer 14 and the master substrate 12 combined together, from the original plate; and punching out the outer circumference and the center hole 12a having desired sizes.

### Method for Producing Master Carrier

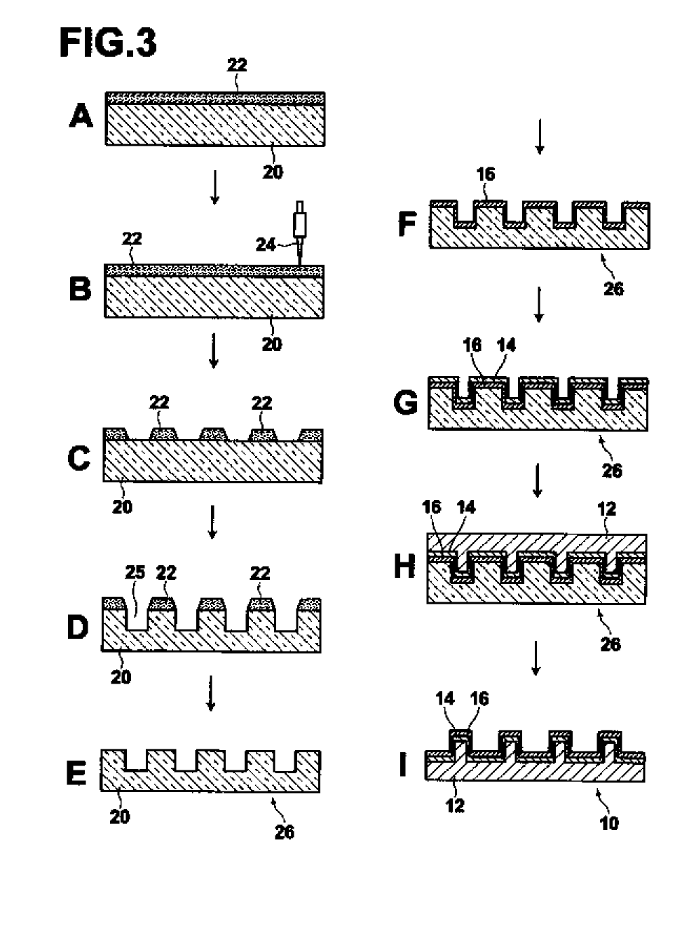

Next, a method for producing the master carrier 10 (mold) is described based on FIG. 3. First, as shown at “A” in FIG. 3, on a substrate 20, which is a silicon wafer having a smooth surface (or which may be a glass plate or a quartz glass plate), an electron beam resist solution is coated by spin coating, or the like, to form a resist layer 22 (a resist coating step), and a baking treatment (pre-baking) is carried out.

Then, the substrate 20 is placed on a high-precision rotating stage or X-Y stage of an electron beam exposure device (not shown). While the substrate 20 is rotated, an electron beam 24, which is modulated according to a servo signal, is applied (at “B” in FIG. 3) to write, through exposure with the beam, a predetermined pattern on substantially the entire surface of the resist layer 22 (an electron beam writing step). For example, a pattern corresponding to a servo signal, which extends in the form of lines from the center of rotation in the track width direction (the pattern shape of the ridge portions shown in FIG. 1) is written on portions corresponding to individual frames of individual tracks in the circumference direction.

Then, as shown at “C” in FIG. 3, the resist layer 22 is developed and the exposed portions thereof are removed to form a coating layer having a desired thickness, which is formed by remaining portions of the resist layer 22. The coating layer serves as a mask in the subsequent step (i.e., an etching step). After the development, another baking treatment (post-baking) is carried out in order to increase an adhesion force between the resist layer 22 and the substrate 20.

Then, as shown at “D” in FIG. 3, portions of the substrate 20 is removed (etched) to a predetermined depth from the surface through openings 25 of the resist layer 22. The etching may be achieved through an anisotropic etching process in order to minimize undercut (side etching). An example of the anisotropic etching to be used may be reactive ion etching (RIE).

Then, as shown at “E” in FIG. 3, the resist layer 22 is removed. Examples of the process used to remove the resist layer 22 include ashing as a dry process, and removal with a releasing liquid as a wet process. Through the ashing step, a Si original plate 26 with a reverse pattern of the desired groove-ridge pattern formed thereon is produced.

Then, as shown at “F” in FIG. 3, a release layer forming step is carried out to form the release layer 16, which is conductive and has a uniform thickness, on the surface of the groove-ridge pattern of the Si original plate 26. Examples of the material forming the release layer 16 may include metals having an ionization tendency lower than that of hydrogen, specifically, a metal film containing at least one metal selected from the group consisting of platinum (Pt), osmium (Os), iridium (Ir), ruthenium (Ru) and palladium (Pd) belonging to platinum group and gold (Au). That is, the release layer 16 may be made of a single metal or an alloy (including an alloy of a metal selected from the above group and another metal, such as PtNi or RuNi). The metal used to form the release layer 16 may optionally be Pt, Os and/or Ir, or may further optionally be Pt.

The process used to form the release layer 16 may be a metal film forming process selected from sputtering, vapor deposition, ion plating, ALD (atomic layer deposition), CVD (chemical vapor deposition) and electroless plating. In this example, the release layer 16 is a Pt film formed through sputtering. The above-mentioned sputtering may be bias sputtering or ion beam sputtering, in view of coatability of the groove-ridge pattern and material selection.

The film thickness of the release layer 16 may be in the range from 1 to 30 nm, may optionally be in the range from 1 to 20 nm, or may further optionally be in the range from 2 to 10 nm. The “film thickness of the release layer” herein refers to the film thickness of the release layer at a flat surface which is not influenced by the groove-ridge pattern, and the actual film thickness at a portion which is influenced by the groove-ridge pattern may be out of the specified range. This also applies to the film thicknesses of a conductive layer, the magnetic layer, a filling layer and a metal substrate, which will be described later.

If the film thickness of the release layer 16 is thicker than the above range, excessive releasability is provided. This may cause release of the duplicated plate (mold) from the Si original plate immediately after the electroforming is started due to stress in the film being electroformed, and may result in a failure such as “wrinkle” or “hole”.

In a case where the film thickness is not sufficient, such that sufficient conductivity cannot be provided only by the release layer 16, a conductive layer made of a conductive metal, such as Ni, may further be formed after the release layer 16 has been formed. That is, after the release layer forming step, a conductive layer forming step may be carried out to form the conductive metal layer on the release layer 16 through a metal film forming method, such as sputtering, vapor deposition, ion plating, ALD, CVD or electroless plating. For example, after a 2 nm-thick Pt release layer has been formed, a 6 nm-thick Ni conductive layer may be formed. Similarly to the formation of the release layer, the above-mentioned sputtering may be bias sputtering or ion beam sputtering, in view of coatability of the groove-ridge pattern and material selection.

In a case where excessive releasability is provided to make the patterning difficult when only the above-described single metal, such Pt, Os, Ir, Au, Ru or Pd, is used, and it is desired to control the release force, the release layer may be formed using an alloy containing any of these metals, such as Pt₃₀Ni₇₀, for example.

Then, as shown at “G” in FIG. 3, a magnetic layer forming step is carried out to form the magnetic layer 14 made of a magnetic material on the release layer 16. It should be noted that the magnetic layer 14 may be formed between the release layer 16 and the conductive layer. In this case, the magnetic layer forming step is carried out between the release layer forming step and the conductive layer forming step. Alternatively, the magnetic layer 14 may be formed after the conductive layer has been formed. In this case, the magnetic layer forming step is carried out after the conductive layer forming step.

The magnetic layer 14 may be formed by forming a film of the magnetic material through a vacuum film forming process, such as vacuum vapor deposition, sputtering or ion plating, ALD, CVD or plating (including electroless plating). Examples of the magnetic material forming the magnetic layer 14 may include Co, Co alloys (such as CoNi, CoNiZr, CoNbTaZr), Fe, Fe alloys (such as FeCo, FeCoNi, FeNiMo, FeAlSi, FeAl, FeTaN), Ni, and Ni alloys (such as NiFe). In particular, FeCo or FeCoNi may be used. The thickness of the magnetic layer 14 may be in the range from 10 nm to 500 nm.

Then, as shown at “H” in FIG. 3, an electroforming step is carried out to form the master substrate (metal substrate) 12 (a Ni electroformed film in this example) having a desired thickness through electroforming (electrodeposition) with the release layer 16 and the magnetic layer 14 formed on the surface of the Si original plate 26 being used as a cathode.

The electroforming step is achieved by immersing the Si original plate 26 in an electrolyte of an electroforming apparatus, and applying an electric current between the cathode formed by a layer which is conductive (the release layer 16 and the magnetic layer 14 in this embodiment) on the Si original plate 26 and an anode. At this time, it is required to control conditions, such as concentration and pH of the electrolyte and how the electric current should be applied, to be optimal conditions to form the Ni electroformed film, which forms the master substrate 12, without distortion.

After the electroforming has been completed, the Si original plate 26 with the master substrate 12 having the predetermined thickness formed thereon is removed from the electrolyte of the electroforming apparatus, and is dipped in pure water in a release bath (not shown).

Then, a release step is carried out in the release bath to release the master carrier 10, which is the duplicated plate and includes the release layer 16, the magnetic layer 14 and the master substrate 12 combined together, from the Si original plate 26 to provide the master carrier 10 as shown at “I” in FIG. 3. Thus, a reversed groove-ridge pattern of the groove-ridge pattern formed on the Si original plate 26 is formed on the surface of the master carrier 10.

In a case where a protective layer is formed on the release layer 16, the master carrier 10 released from the Si original plate 26 is punched to provide the inner diameter and the outer diameter of predetermined sizes, and then a carbon film is formed through sputtering.

In this manner, the master carrier 10 for magnetic transfer is produced. In a case where a larger magnetic intensity is desired, another magnetic layer may be formed on the master carrier 10 which has been released from the Si original plate 26 and punched, and then the protective layer may be formed.

According to the above-described production method, good releasability during the release step of the master carrier 10, which is the duplicated plate, can be provided, thereby preventing generation of chipped tips of the ridge portions of the groove-ridge pattern. Thus, the master carrier 10 for magnetic transfer which has a precise reverse shape of the groove-ridge shape of the Si original plate 26 can be provided to allow magnetic transfer with good signal quality.

Further, as shown in FIG. 1, the ridge portions of the groove-ridge pattern of the master carrier 10 have a trapezoidal cross section in the track direction, and release of the master carrier 10 from the Si original plate 26 becomes more difficult as a rising angle of the ridge portions becomes closer to 90° (i.e., as the cross section of the ridge portions becomes closer to a rectangle).

According to the production method of this example, improved releasability of the master carrier 10, which is the duplicated plate, is provided, and therefore, the sectional shape of the ridge portions can be made closer to a rectangle. This allows groove-ridge patterns with higher density and higher precision, thereby allowing transfer of information to the magnetic recording medium with higher density and higher precision. Further, in the case of the master carrier for magnetic transfer, the master carrier has, on the surface thereof, the high-density and high-precision fine groove-ridge pattern containing at least a servo pattern formed by the magnetic layer. When the master carrier is placed on a magnetic recording medium and a magnetic field is applied thereto using a magnetic transfer technique, a magnetized pattern corresponding to the pattern of the magnetic layer can be transferred with high density and high precision to the magnetic recording medium, and thus the medium having excellent properties can be produced in a simple manner.

Moreover, according to the production method of this example, since no residue is left as in a case where a releasing agent is used on the Si original plate 26, repeated use of the single Si original plate 26 is achieved, so that a plurality of master carriers 10 (for example, 30 master carriers) can be produced from the same Si original plate 26. This allows reduction of production cost.

### Preferred Form of Ridge Portions

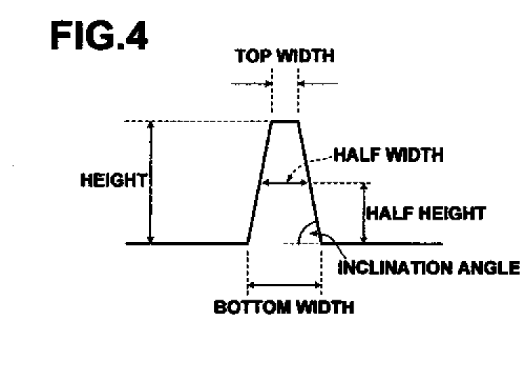

In the process shown in FIG. 3, the sectional shape of the groove-ridge pattern formed on the master carrier 10 schematically shown in the drawing is rectangular. However, actually, as the density of the information to be recorded increases, the ridge portions becomes narrower at the top thereof and higher (or higher ratio of the height to the width), as shown in FIG. 4, than that of the shape shown in FIG. 1, i.e., the sectional shape of the ridge portions has higher aspect ratio. The releasability of the master carrier 10 from the Si original plate 26 changes along with the change of the aspect ratio.

FIG. 4 is a schematic sectional view of the trapezoidal shape of the ridge portion of the above-described master carrier 10. It should be noted that, in FIG. 4, the layer structure of the master carrier 10 is not shown for convenience sake. The “height” of the ridge portion and the “inclination angle” of the slopes of the trapezoid are as shown in the drawing. The “half width”, which will be described later, is defined as indicating a width of the ridge portion at a half the height of the ridge portion. The aspect ratio of the trapezoidal shape of the ridge portion is defined as “height/half width”.

In this embodiment, the height of the ridge portion of the master carrier may be in the range from 5 to 800 nm, and the half width of the ridge portion may be in the range from 3 to 20000 nm. Optionally, the height may be in the range from 10 to 600 nm and the half width may be in the range from 7 to 5000 nm. Further optionally, the height may be in the range from 20 to 400 nm and the half width may be in the range from 10 to 500 nm. Specifically, a plurality of ridge portions having the height of 100 nm and the half width ranging from 40 nm to 250 nm, for example, may be present in the same master carrier 10.

The aspect ratio may be in the range from 0.05 to 50.0. Optionally, the aspect ratio may be in the range from 0.02 to 10.0. Further optionally, the aspect ratio may be in the range from 0.2 to 5.0. Specifically, a plurality of ridge portions having an aspect ratio ranging from 0.5 (=100/250) to 2.5 (=100/40), for example, may be present in the same master carrier 10.

The inclination angle of the slopes of the trapezoid may be in the range from 20° to 90°. Optionally, the inclination angle may be in the range from 30° to 89°. Further optionally, the inclination angle may be in the range from 40° to 88°. Specifically, the inclination angle may, for example, be about 82°.

It should be noted that, by rounding the shape (corners) of the bottom portion of the ridge shape, releasability of the duplicated plate is further improved from that of the duplicated plate with ridge portions having a strict trapezoidal shape.

The trapezoidal shape of the ridge portions of the master carrier 10 can be achieved through RIE (reactive ion etching). The inclination angle of the trapezoidal shape can be controlled by changing etching rate, type of etching gas, mixing ratio, etc.

### Second Embodiment of Method for Producing Master Carrier

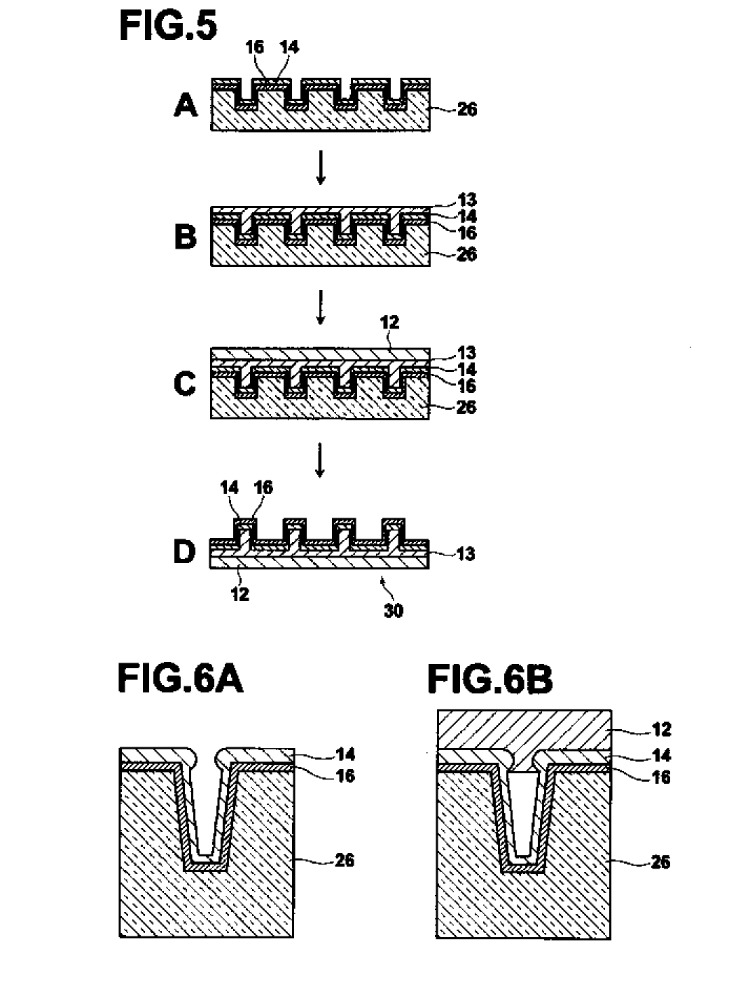

Next, a method for producing a master carrier according to another embodiment is described based on FIG. 5. This production method differs from the method described above with reference to

FIG. 3 in that, after the release layer has been formed and before the master substrate (metal substrate) is formed, a filling layer is formed to fill the groove portions of the groove-ridge pattern of the Si original plate. That is, this method includes the same steps as the steps shown at “A” to “G” in FIG. 3 of the above-described method. It should be noted that the same components as those in the above-described embodiment are denoted by the same reference numerals, and explanations thereof are omitted unless otherwise required.

FIG. 5 shows at “A” a schematic sectional view of the Si original plate in a state where the release layer 16 and the magnetic layer 14 are formed in this order after the groove-ridge pattern has been formed on the surface of the silicon wafer original plate 20. Namely, this state corresponds to the state shown at “G” in FIG. 3.

Then, in the production method of this embodiment, the filling layer 13 is formed (shown at “B” in FIG. 5) from the state shown at “A” in FIG. 5. Thereafter, the master substrate 12 is formed through electroforming (shown at “C” in FIG. 5) and the duplicated plate is released from the Si original plate 26 to provide a master carrier 30 (shown at “D” in FIG. 5).

The filling layer 13 can be formed through a metal film forming process selected from sputtering, vapor deposition, ion plating, ALD, CVD, and electroless plating. The above-mentioned sputtering may be bias sputtering or ion beam sputtering, in view of fillability of the groove-ridge pattern and material selection. In particular, bias sputtering or ion beam sputtering, or ALD, which provides good fillability of the groove portions of the groove-ridge pattern, may be preferred to form the filling layer 13. The material forming the filling layer 13 is not particularly limited, and examples thereof may include those listed above for the conductive layer, the magnetic layer or the metal substrate formed through electroforming. That is, the conductive layer or the magnetic layer may also serve as the filling layer.

As described above, in production of a mold having a fine groove-ridge pattern, there is a problem of chipped ridge portions in the duplicated plate that are generated when the duplicated plate is released from the original plate. As the major cause of this problem, the large adhesion between the original plate and the duplicated plate has been mentioned above. In addition, formation of non-filled areas in the ridge portions of the duplicated plate is believed to be another cause. For example, as shown in FIGS. 6A and 6B, the non-filled areas are formed because a relatively thick film (for example, the magnetic layer 14) formed on the groove-ridge pattern narrows the openings of the groove portions (shown in FIG. 6A), and this hinders the metal material from filling the groove portions to the bottoms thereof in the subsequent electroforming step. The filling layer 13 is formed in particular to address this problem by filling the groove portions of the groove-ridge pattern. For example, in a case where the filling layer is formed through bias sputtering, film deposition of the sputtered particles and Ar ion etching caused by application of a bias simultaneously proceed on the surface where the film is formed. Therefore, parts of the film deposited around the openings of the groove portions are re-sputtered and can fill the groove portions to the bottoms thereof. It should be noted that, when the film has been deposited to a sufficient thickness, a flat surface is provided at the filled areas.

As described above, the master carrier of this embodiment provided with the release film containing a metal having an ionization tendency lower than that of hydrogen provides the same effect as that of the above-described embodiment. In addition, the master carrier of this embodiment is further provided with the filling layer 13 to fill the groove portions. Therefore, in the master carrier of this embodiment, even when the groove-ridge pattern has a narrower line width, the groove portions can satisfactorily be filled without generating the non-filled areas, and generation of chipped ridge portions in the duplicated plate can be prevented with higher reliability.

### Molds of Other Forms

The mold described in the above embodiment is a master carrier for magnetic transfer. As described above, the invention is also applicable to a mold for discrete track media, a mold for nanoimprint, etc.

The molds for discrete track media and for nanoimprint having a fine groove-ridge pattern are used to transfer the shape of the fine groove-ridge pattern on the surface thereof by being pressed against an object. These molds have a structure that is similar to the structure of the master carrier 10, except that the magnetic layer 14 is not provided. Namely, these molds are formed by forming a metal substrate, which is equivalent to the master substrate 12, through electroforming on the release layer 16.

Therefore, such molds can be produced by the same method as shown in FIG. 3, except that the magnetic layer forming step shown at “G” in FIG. 3 is omitted. Although the shape of the groove-ridge pattern of these molds is different from that of the master carrier for magnetic transfer, these molds are the same as the above-described mold for magnetic transfer in that they are formed by forming the groove-ridge pattern with high density and high precision on a metal substrate, which is a base material, with ensuring good releasability provided by a release layer formed to conform to the groove-ridge pattern, and releasing the mold with the release layer adhering to the surface thereof from an Si original plate. The same applies to a mold (stamper) for manufacturing optical disks.

According to the above-described method for producing a mold, a mold having the release layer, which contains a metal, such as Pt, having an ionization tendency lower than that of hydrogen, and a high density and high-precision groove-ridge pattern on the surface thereof can be produced in a simple manner. This also ensures releasability when the mold is used for press transfer. In particular, in a case of an imprint mold, when shape patterning is carried out using an imprinting technique, the shape can be transferred to the surface of a medium at a time by pressing the mold against the surface of a resin layer, which serves as a mask during a process to form a magnetic recording medium. Similarly, magnetic disk media, such as discrete track media or bit pattern media, having excellent properties can be produced in a simple manner.

As described above, depending on various forms of the mold, the layer structure of the mold may take the following patterns. The first pattern is a layer structure including [the release layer/the conductive layer/the magnetic layer/the metal substrate] in this order. The second pattern is a layer structure including [the release layer/the magnetic layer/the conductive layer/the metal substrate] in this order. The third pattern is a layer structure including [the release layer/the magnetic layer/the metal substrate] in this order. The fourth pattern is a layer structure including [the release layer/the conductive layer/the metal substrate] in this order. The fifth pattern is a layer structure including [the release layer/the metal substrate] in this order. The sixth pattern is a layer structure including [the release layer/the magnetic layer/the filling layer (which also serves as the conductive layer)/the metal substrate] in this order. The seventh pattern is a layer structure including [the release layer/the filling layer (which also serves as the conductive layer and the magnetic layer)/the metal substrate] in this order.

For example, if the above-described master carrier for magnetic transfer is provided with a release layer made of Pt, good releasability is achieved with a film thickness in the range from 2 to 5 nm. If the film thickness of the Pt release layer exceeds 6 nm, wrinkles may be generated on the duplicated plate depending on electroforming conditions of the Ni substrate. On the other hand, if the Pt release layer has a film thickness in the range from 2 to 3 nm, the Pt release layer is not a continuous film. In this case, if the magnetic layer is not formed, sufficient electric conductivity required for electroforming is not provided. Therefore, for example, after a 2 nm-thick Pt release layer is formed, a 6 nm-thick Ni conductive layer may be formed to ensure conductivity for electroforming. The conductive layer may also be formed in a case where the magnetic layer is formed. In this case, for example, the layer structure may be Pt release layer (3 nm-thick)/Ni conductive layer (6 nm-thick)/FeCo magnetic layer (30 nm-thick)/Ni electroformed layer (150 μm-thick). It should be noted that the layer thicknesses vary depending on a combination of type of the mold, material forming each layer, ratios of thicknesses of the individual layers, etc., and the above examples of the thicknesses the individual layers are not optimal values.

### EXAMPLES

### Example 1

As an example of the layer structure of a mold (master carrier) for magnetic transfer, a 3 nm-thick Pt release layer and a 20 nm-thick FeCo magnetic layer were formed in this order through sputtering on the surface of a Si original plate, which had on the surface thereof a fine groove pattern having a half width of 30 nm and a height of 100 nm. Then, a 150 μm-thick Ni master substrate was formed through electroforming on the Si original plate having the two layers, the Pt release layer (3 nm) and the FeCo layer (20 nm), formed thereon to form a duplicated plate. The duplicated plate was released from the Si original plate to provide a master carrier for magnetic transfer having on the surface thereof a ridge pattern, which is a reverse pattern of the groove pattern, and including the magnetic layer and the Pt release layer formed on the surface of the reverse pattern.

### Example 2

As an example of the layer structure of a mold for discrete track media, a 9 nm-thick Ru release layer was formed through sputtering on the surface of the Si original plate, which had on the surface thereof a fine groove pattern having a half width of 20 nm and a height of 60 nm. Then, a 150 μm-thick Ni substrate was formed through electroforming on the Si original plate with the 9 nm-thick Ru release layer formed thereon to form a duplicated plate. The duplicated plate was released from the Si original plate to provide a mold for shape transfer having on the surface thereof a ridge pattern, which is a reverse pattern of the groove pattern, and including the Ru release layer formed on the surface of the reverse pattern.

### Example 3

As an example of the layer structure of a mold (master carrier) for magnetic transfer, a 3 nm-thick Pt release layer was formed through sputtering on the surface of a Si original plate, which had on the surface thereof a fine groove pattern having a half width of 20 nm and a height of 60 nm, and then a 60 nm-thick FeCo magnetic layer was formed through bias sputtering to fill the groove portions of the Si original plate. Then, a 150 μm-thick Ni master substrate was formed through electroforming on the Si original plate having the two layers, the Pt release layer (3 nm) and the FeCo layer (60 nm), formed thereon to form a duplicated plate. The duplicated plate was released from the Si original plate to provide a master carrier for magnetic transfer having on the surface thereof a ridge pattern, which is a reverse pattern of the groove pattern, and including the magnetic layer and the Pt release layer formed on the surface of the reverse pattern.

### Example 4

As an example of the layer structure of a mold for discrete track media, a 9 nm-thick Ru release layer was formed through sputtering on the surface of a Si original plate, which had on the surface thereof a fine groove pattern having a half width of 20 nm and a height of 60 nm, and then a 60 nm-thick Ru conductive layer was formed through bias sputtering to fill the groove portions of the Si original plate. Then, a 150 μm-thick Ni substrate was formed through electroforming on the Si original plate having the two layers, the Ru release layer (9 nm) and the Ru conductive layer (60 nm), formed thereon to form a duplicated plate. The duplicated plate was released from the Si original plate to provide a mold for shape transfer having on the surface thereof a ridge pattern, which is a reverse pattern of the groove pattern, and including the Ru conductive layer and the Ru release layer formed on the surface of the reverse pattern.

### Example 5

As an example of the layer structure of a mold (master carrier) for magnetic transfer, a 3 nm-thick Pt release layer was formed through sputtering on the surface of a Si original plate, which had on the surface thereof a fine groove pattern having a half width of 20 nm and a height of 60 nm, and then a 60 nm-thick FeCo magnetic layer was formed through ion beam sputtering to fill the groove portions of the Si original plate. Then, a 150 μm-thick Ni master substrate was formed through electroforming on the Si original plate having the two layers, the Pt release layer (3 nm) and the FeCo layer (60 nm), formed thereon to form a duplicated plate. The duplicated plate was released from the Si original plate to provide a master carrier for magnetic transfer having on the surface thereof a ridge pattern, which is a reverse pattern of the groove pattern, and including the magnetic layer and the Pt release layer formed on the surface of the reverse pattern.

### Example 6

As an example of the layer structure of a mold for discrete track media, a 9 nm-thick Ru release layer was formed through sputtering on the surface of a Si original plate, which had on the surface thereof a fine groove pattern having a half width of 20 nm and a height of 60 nm, and then a 60 nm-thick Ru conductive layer was formed through ion beam sputtering to fill the groove portions of the Si original plate. Then, a 150 μm-thick Ni substrate was formed through electroforming on the Si original plate having the two layers, the Ru release layer (9 nm) and the Ru conductive layer (60 nm), formed thereon to form a duplicated plate. The duplicated plate was released from the Si original plate to provide a mold for shape transfer having on the surface thereof a ridge pattern, which is a reverse pattern of the groove pattern, and including the Ru conductive layer and the Ru release layer formed on the surface of the reverse pattern.

### Example 7

As an example of the layer structure of a mold for discrete track media, a 9 nm-thick Ru release layer was formed through sputtering on the surface of a Si original plate, which had on the surface thereof a fine groove pattern having a half width of 20 nm and a height of 60 nm, and then a 60 nm-thick Ru conductive layer was formed through ALD to fill the groove portions of the Si original plate. Then, a 150 μm-thick Ni substrate was formed through electroforming on the Si original plate having the two layers, the Ru release layer (9 nm) and the Ru conductive layer (60 nm), formed thereon to form a duplicated plate. The duplicated plate was released from the Si original plate to provide a mold for shape transfer having on the surface thereof a ridge pattern, which is a reverse pattern of the groove pattern, and including the Ru conductive layer and the Ru release layer formed on the surface of the reverse pattern.

### Example 8

As an example of the layer structure of a mold for discrete track media, a 69 nm-thick Ru release layer was formed through ALD on the surface of a Si original plate, which had on the surface thereof a fine groove pattern having a half width of 20 nm and a height of 60 nm. Then, a 150 μm-thick Ni substrate was formed through electroforming on the Si original plate having the Ru release layer (69 nm) formed thereon to form a duplicated plate. The duplicated plate was released from the Si original plate to provide a mold for shape transfer having on the surface thereof a ridge pattern, which is a reverse pattern of the groove pattern, and including the Ru release layer formed on the surface of the reverse pattern.

### Comparative Example 1

A duplicated plate of Comparative Example 1 was provided in the same manner as in Example 1, except that the Pt release layer was replaced with a Ni release layer (3 nm-thick). It should be noted that Ni is a metal having higher ionization tendency than hydrogen.

### Comparative Example 2

A duplicated plate of Comparative Example 2 was provided in the same manner as in Example 2, except that the Ru release layer was replaced with a Ni release layer (9 nm-thick).

### Measurement 1

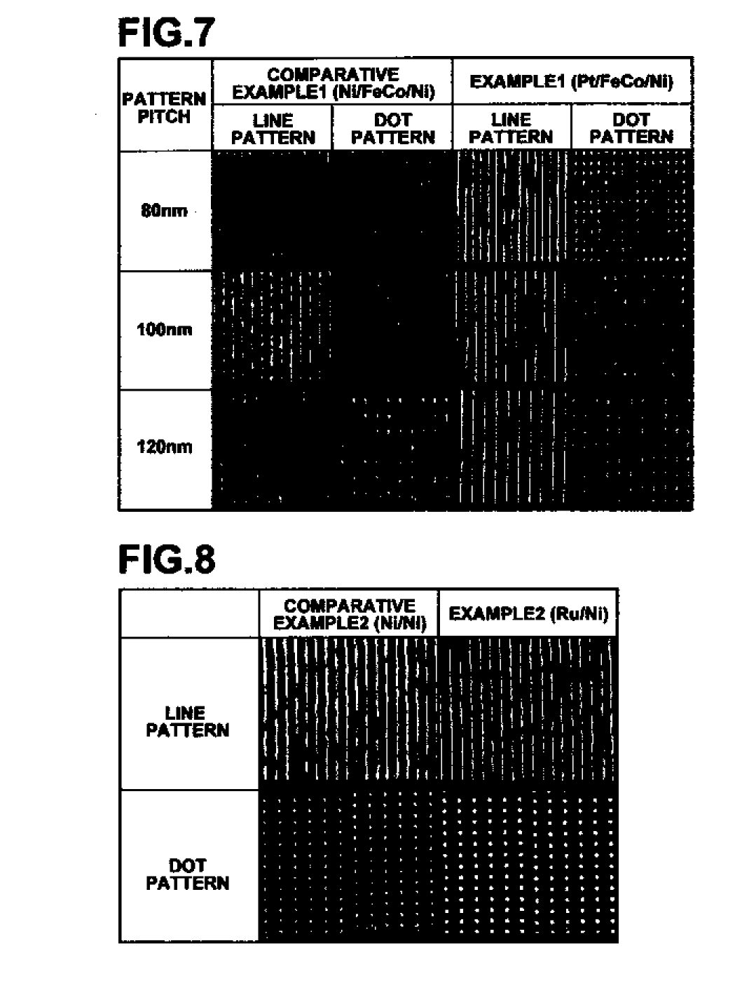

For each of the duplicated plates of Example 1 (Pt: 3 nm/FeCo: 20 nm/Ni: 150 μm) and Comparative Example 1 (Ni: 3 nm/FeCo: 20 nm/Ni: 150 μm), which are examples of the mold (master carrier) for magnetic transfer, surface condition of the ridge pattern of the duplicated plate released from the Si original plate was observed using a scanning electron microscope (SEM). The results are shown in FIG. 7.

The measurement and observation were conducted on the ridge pattern formed on each mold, which included a line pattern and a dot pattern having a height of 100 nm and a half width of 30 nm, with varied pattern pitches of 80 nm, 100 nm and 120 nm.

As can be seen from the SEM micrographs shown in FIG. 7, the line pattern of Example 1 had narrower and clearer ridge shapes (portions appearing white in the photographs) than those of Comparative Example 1, and the dot pattern of Example 1 had smaller and clearer dots of ridge portions than those of Comparative Example 1. Thus, it was confirmed that a good pattern shape was reproduced and appropriate releasability was provided by the Pt release layer in Example 1. In contrast, the ridge pattern of Comparative Example 1 included chipped portions in the ridge shape. This means that the Ni release layer failed to provide sufficient releasability.

### Measurement 2

For each the duplicated plates of Example 2 (Ru: 9 nm/Ni: 150 μm) and Comparative Example 2 (Ni: 9 nm/Ni: 150 μm), which are examples of the mold for discrete track media, surface condition of the ridge pattern of the duplicated plate released from the Si original plate was observed using a scanning electron microscope (SEM). The results are shown in FIG. 8.

The pattern shapes for comparison included a line pattern and a dot pattern having a height of 60 nm and a half width of 20 nm.

As can be seen from the SEM micrographs shown in FIG. 8, the line pattern of Example 2 had narrower and clearer ridge shapes (portions appearing white in the photographs) than those of Comparative Example 2, and the dot pattern of Example 2 had smaller and clearer dots of ridge portions than those of Comparative Example 2. Thus, it was confirmed that a good pattern shape was reproduced and appropriate releasability was provided by the Ru release layer in Example 2.

### Release Test

In addition to the above-described measurement and observation of the release condition of the released surface, the effect was confirmed through measurement of release force in simulation.

In this release test method, a test specimen, a metal rivet and a tensile tester were used. The test specimen was prepared by forming a simulation groove-ridge pattern, which had closely arranged dot or line groove portions, on a Si wafer, forming a release layer of one of different materials through sputtering on the groove-ridge pattern, and forming a Ni base film through sputtering on the release layer. To the Ni base film of the test specimen, one end of the metal rivet (rivets having the same shape were used for all the specimens) was fixed with an adhesive (epoxy adhesive). A tensile jig was fixed to the other end of the metal rivet. Then, the tensile jig was pulled with the tensile tester to measure the tensile force exerted by the tensile tester when each test specimen was released, and the forces required to release the specimens, i.e., the release forces [MPa] were compared.

In the test results, the Pt release layer required a particularly small release force, which was about ⅓ of that of the Ni release layer, and was ⅙ of that of the FeCo layer. This property is suitable for a release condition in manufacture of duplicated molds of actual master carriers for magnetic transfer.

Through analysis of the test results of the above-described release test, it was presumed that there is a relationship between the releasability and the oxidation degree (ratio of oxygen element to metal element) of the metal forming the release layer. Thus, it is believed that higher releasability is provided by forming the release layer with a metal having an ionization tendency lower than that of hydrogen, i.e., a metal which is not easily oxidized. The reason is believed that a binding force between a metal oxide, which is the metal in the release layer being oxidized, and the silicon oxide in the Si original plate is the origin of the adhesion force, and therefore the Pt release layer, which has a oxidation degree lower than that of the Ni release layer, as described above, provides the higher releasability. Considering this, it is effective to form the release layer of a metal film (of a single metal or an alloy) which contains, as the metal having an ionization tendency lower than that of hydrogen, at least one metal selected from the group consisting of platinum (Pt), osmium (Os), iridium (Ir), ruthenium (Ru) and palladium (Pd) belonging to platinum group and gold (Au).

What is claimed is:

1. A method for producing a mold, the method comprising:
a release layer forming step of forming, on a surface of a Si original plate having a groove-ridge pattern, a release layer comprising a metal film containing a metal having an ionization tendency lower than that of hydrogen;
an electroforming step of electroforming, after the release layer has been formed, a metal substrate to fill groove portions of the groove-ridge pattern; and
a releasing step of releasing a duplicated plate including the release layer and the metal substrate from the Si original plate after the electroforming step,
thereby providing the mold formed by the duplicated plate.

2. The method for producing a mold as claimed in claim 1, wherein the metal film containing the metal having an ionization tendency lower than that of hydrogen comprises a metal film containing at least one metal selected from the group consisting of Pt, Os, Ir, Au, Ru and Pd.

3. The method for producing a mold as claimed in claim 1, further comprising, between the release layer forming step and the electroforming step,
a magnetic layer forming step of forming a magnetic layer conforming to the groove-ridge pattern of the release layer.

4. The method for producing a mold as claimed in claim 1, wherein the release layer forming step comprises forming the release layer through a process selected from sputtering, vapor deposition, ion plating, ALD (atomic layer deposition), CVD (chemical vapor deposition) and electroless plating.

5. The method for producing a mold as claimed in claim 4, wherein the sputtering comprises bias sputtering or ion beam sputtering.

6. The method for producing a mold as claimed in claim 1, further comprising, between the release layer forming step and the electroforming step,
a conductive layer forming step of forming a conductive layer, the conductive layer being made of a conductive metal and conforming to the groove-ridge pattern of the release layer.

7. The method for producing a mold as claimed in claim 6, wherein the conductive layer forming step comprises forming the conductive layer through a process selected from sputtering, vapor deposition, ion plating, ALD, CVD and electroless plating.

8. A method for producing a mold, the method comprising:
a release layer forming step of forming, on a surface of a Si original plate having a groove-ridge pattern, a release layer comprising a metal film containing a metal having an ionization tendency lower than that of hydrogen;
a filling layer forming step of forming, after the release layer has been formed, a filling layer to fill groove portions of the groove-ridge pattern;
an electroforming step of electroforming a metal substrate after the filling layer has been formed; and
a releasing step of releasing from the Si original plate a duplicated plate including the release layer, the filling layer and the metal substrate after the electroforming step,
thereby providing the mold formed by the duplicated plate.

9. The method for producing a mold as claimed in claim 8, wherein the metal film containing a metal having an ionization tendency lower than that of hydrogen comprises a metal film containing at least one metal selected from the group consisting of Pt, Os, Ir, Au, Ru and Pd.

10. The method for producing a mold as claimed in claim 8, wherein the release layer forming step comprises forming the release layer through a process selected from sputtering, vapor deposition, ion plating, ALD, CVD and electroless plating.

11. The method for producing a mold as claimed in claim 10, wherein the sputtering comprises bias sputtering or ion beam sputtering.

12. The method for producing a mold as claimed in claim 8, wherein the filling layer comprises a metal material.

13. The method for producing a mold as claimed in claim 8, further comprising, between the release layer forming step and the filling layer forming step, a magnetic layer forming step of forming a magnetic layer conforming to the groove-ridge pattern of the release layer.

14. The method for producing a mold as claimed in claim 8, wherein the filling layer forming step comprises forming the filling layer through a process selected from sputtering, vapor deposition, ion plating, ALD, CVD and electroless plating.

15. The method for producing a mold as claimed in claim 14, wherein the sputtering comprises bias sputtering or ion beam sputtering.

16. A mold having a groove-ridge pattern, the mold comprising:
a metal substrate formed through electroforming and having a groove-ridge pattern; and
a release layer disposed on a surface of the groove-ridge pattern of the metal substrate, the release layer comprising a metal film containing a metal having an ionization tendency lower than that of hydrogen.

17. The mold as claimed in claim 16, wherein the metal film containing the metal having an ionization tendency lower than that of hydrogen comprises a metal film containing at least one metal selected from the group consisting of Pt, Os, Ir, Au, Ru and Pd.

18. The mold as claimed in claim 16, further comprising a magnetic layer conforming to the groove-ridge pattern, the magnetic layer being disposed between the metal substrate and the release layer.

19. The mold as claimed in claim 16, wherein the release layer has a film thickness in a range from 1 to 30 nm.

20. The mold as claimed in claim 16, further comprising, between the release layer and the metal substrate, a conductive layer made of a conductive metal and conforming to the groove-ridge pattern.
